(19) United States
(12) Patent Application Publication
(10) Pub. No.: US 2006/0077726 A1
(43) Pub. Date: Apr. 13, 2006

(54) Data transfer method, storage apparatus and computer-readable storage medium

(75) Inventor: Masaru Shimmitsu, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 11/041,863

(22) Filed: Jan. 25, 2005

(30) Foreign Application Priority Data
Oct. 8, 2004 (JP) 2004-296468

(51) Int. Cl. G11C 7/10

(52) U.S. Cl. 365/189.05

(57) ABSTRACT

A data transfer method transfers data stored in a first storage part to a second storage part within a storage apparatus. All data stored in units of data regions within the first storage part are transferred to the second storage part, and with respect to each data region for which a data transfer is unsuccessful, redundant data are transferred to the second storage part from a third storage part which stores the redundant data identical to the data stored in the first storage part.

### BACKGROUND OF THE INVENTION

This application claims the benefit of a Japanese Patent Application No. 2004-296468 filed Oct. 8, 2004, in the Japanese Patent Office, the disclosure of which is hereby incorporated by reference.

1. Field of the Invention

The present invention generally relates to data transfer methods, storage apparatuses and computer-readable storage media, and more particularly to a data transfer method for transferring data stored in a storage part that is a disconnecting target to another storage part when disconnecting the disconnecting target storage part in which a failure is generated or predicted, a storage apparatus which employs such a data transfer method, and a computer-readable storage medium which stores a program for causing a computer to carry out such a data transfer.

2. Description of the Related Art

When a failure is generated or predicted in a storage part such as a hard disk drive (HDD), it is necessary to replace the HDD. When disconnecting the HDD in which the failure is generated or predicted from a storage apparatus such as a disk apparatus, it is necessary to transfer the data stored in the HDD that is the disconnecting target to another HDD.

According to a first conventional method, when the data transfer is to be made between the HDDs due to replacement of the HDD, the data transfer is made from the transfer source HDD that is to be disconnected from the disk apparatus to the transfer destination HDD. However, if an abnormality is detected in the transfer source HDD during the data transfer, the transfer source HDD is disconnected from the disk apparatus. In such a case, not all of the data to be transferred are transferred to the transfer destination HDD, and a data loss is generated.

According to a second conventional method, the HDD that is to be disconnected from the disk apparatus is disconnected from the disk apparatus before the data transfer starts, and the data transfer is made using the redundant data stored in another HDD. In this case, all of the data to be transferred are transferred in divisions by being segmented in predetermined units such as blocks and regions. Information that is related to the data transfer and is managed in the second conventional method includes a progress state indicating the block to which the data transfer process, successively carried out from the starting block, has progressed. However, the second conventional method does not manage information indicating whether or not the transfer of blocks failed during the data transfer or, information indicating whether or not the data transfer was successful.

A Japanese Laid-Open Patent Application No. 5-166287 proposes a third conventional method of avoiding, before happening, a failure caused by a defective disk apparatus after the disk apparatus is started.

In the second conventional method, the data transfer with respect to the HDD in which the failure is generated or predicted is made by disconnecting the HDD and using the redundant data to transfer the data from another HDD to the transfer destination HDD. For this reason, if a medium error or the like is generated in this other HDD that stores the redundant data and the data to be transferred to the transfer destination HDD cannot be formed from the redundant data, a data loss is generated.

According to the third conventional method, the data to be transferred is read from the HDD that is to be disconnected from the disk apparatus, and the read data is copied to another HDD (redundant copy), so as to carry out the data transfer while maintaining redundancy. However, if an abnormality is detected in the HDD that is to be disconnected when carrying out the data transfer, this HDD is disconnected from the disk apparatus even in a state where the data transfer is incomplete. In this case, the data to be transferred to the transfer destination HDD is formed by using the redundant data stored in another HDD, similarly as in the case of the second conventional method. Consequently, a data loss may be generated, similarly as in the case of the second conventional method.

Therefore, according to the conventional methods, there was a problem in that it is impossible to positively prevent a data loss when transferring the data of the HDD that is to be disconnected from the disk apparatus.

### SUMMARY OF THE INVENTION

Accordingly, it is a general object of the present invention to provide a novel and useful data transfer method, storage apparatus and computer-readable storage medium, in which the problems described above are suppressed.

Another and more specific object of the present invention is to provide a data transfer method, a storage apparatus and a computer-readable storage medium, which can positively prevent a data loss when transferring data of a storage part that is to be disconnected.

Still another object of the present invention is to provide a data transfer method for transferring data stored in a first storage part to a second storage part within a storage apparatus, comprising a first step transferring all data stored in units of data regions within the first storage part to the second storage part; and a second step transferring, with respect to each data region for which a data transfer by the first step is unsuccessful, redundant data to the second storage part from a third storage part which stores the redundant data identical to the data stored in the first storage part. According to the data transfer method of the present invention, it is possible to positively prevent a data loss when transferring the data of the storage part that is to be disconnected.

A further object of the present invention is to provide a storage apparatus comprising a first storage part; a second storage part; a third storage part; and a control part configured to control data transfers among the first, second and third storage parts, wherein the control part transfers all data stored in units of data regions within the first storage part to the second storage part, and transfers, with respect to each data region for which a data transfer is unsuccessful, redundant data to the second storage part from the third storage part which stores the redundant data identical to the data stored in the first storage part. According to the storage apparatus of the present invention, it is possible to positively prevent a data loss when transferring the data of the storage part that is to be disconnected.

Another object of the present invention is to provide a computer-readable storage medium which stores a program for causing a computer to transfer data stored in a first storage part to a second storage part within a storage apparatus, the program comprising a first procedure causing the computer to transfer all data stored in units of data regions within the first storage part to the second storage part; and a second procedure causing the computer to transfer, with respect to each data region for which a data transfer by the first step is unsuccessful, redundant data to the second storage part from a third storage part which stores the redundant data identical to the data stored in the first storage part. According to the computer-readable storage medium of the present invention, it is possible to positively prevent a data loss when transferring the data of the storage part that is to be disconnected.

Still another object of the present invention is to provide a storage apparatus comprising a first storage part; a second storage part; and a control part configured to control transfer of data stored in the first storage part to the second storage part when an abnormality is generated in the first storage part, wherein the first storage part is disconnected from the storage apparatus after the transfer of data from the first storage part to the second storage part is completed. According to the storage apparatus of the present invention, it is possible to positively prevent a data loss when transferring the data of the storage part that is to be disconnected.

Other objects and further features of the present invention will be apparent from the following detailed description when read in conjunction with the accompanying drawings.

### BRIEF DESCRIPTION OF THE DRAWINGS

FIG. 1 is a diagram for explaining an embodiment of a data transfer method according to the present invention;

FIG. 2 is a diagram for explaining the embodiment of the data transfer method according to the present invention;

FIG. 3 is a diagram for explaining the embodiment of the data transfer method according to the present invention;

FIG. 4 is a diagram for explaining the embodiment of the data transfer method according to the present invention;

FIG. 5 is a diagram for explaining the embodiment of the data transfer method according to the present invention;

FIG. 6 is a system block diagram showing an important part of an embodiment of a storage apparatus according to the present invention;

FIG. 7 is a diagram showing data regions of HDDs;

FIG. 8 is a flow chart for explaining a data transfer process that is carried out based on a program stored in an embodiment of a computer-readable storage medium according to the present invention;

FIG. 9 is a flow chart for explaining a process of acquiring HDD structure information;

FIG. 10 is a flow chart for explaining a process of creating a data transfer management table;

FIG. 11 is a flow chart for explaining a data transfer process from a replacing target HDD to an auxiliary HDD;

FIG. 12 is a flow chart for explaining a data transfer process from a redundant HDD to an auxiliary HDD;

FIG. 13 is a flow chart for explaining a data read process utilizing a media defect table;

FIG. 14 is a flow chart for explaining a process of inspecting an error log; and

FIG. 15 is a flow chart for explaining a process of selecting a read HDD.

### DESCRIPTION OF THE PREFERRED EMBODIMENTS

In the present invention, when a storage part such as an HDD is to be replaced and data must be transferred between storage parts, as much data transfer that is possible is made from the storage part that is to be disconnected from a storage apparatus. If an abnormality of the storage part that is to be disconnected (transfer source storage part) is detected during the data transfer, the transfer source storage part is not disconnected from the storage apparatus such as a disk apparatus until the data transfer is completed.

Information that is related to the data transfer and is managed includes a progress state indicating the block to which the data transfer process, successively carried out from the starting block, has progressed, and whether or not the transfer of blocks failed during the data transfer or, whether or not the data transfer was successful. By managing the progress state of the data transfer, the transfer source storage part that is to be disconnected is disconnected from the storage apparatus after the data transfer is completed. The information related to the data transfer may be managed as a function of the storage apparatus or the storage part.

Accordingly, when transferring the data between the storage parts, the transfer source storage part that is to be disconnected is not disconnected from the storage apparatus until the completion of the data transfer process. By managing information indicating whether or not the data transfer was successful, the data transfer process can be carried out between the storage parts without data loss with respect to the data transfer from a plurality of storage parts. Hence, it is possible to positively prevent a data loss when transferring the data from the transfer source storage part that is to be disconnected from the storage apparatus.

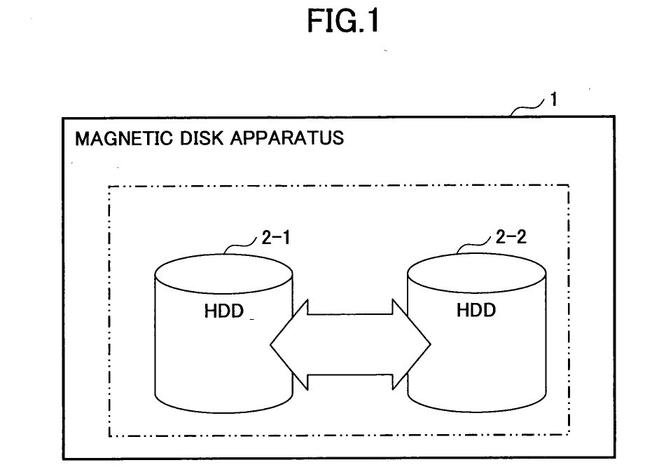

Next, a description will be given of an embodiment of a data transfer method according to the present invention, by referring to FIGS. 1 through 5. FIGS. 1 through 5 are diagrams for explaining this embodiment of the data transfer method. In this embodiment, the present invention is applied to a magnetic disk apparatus having a plurality of HDDs. In FIGS. 1 through 5, a magnetic disk apparatus 1 includes a plurality of HDDs 2-1 through 2-N, and it is assumed for the sake of convenience that a failure is generated or predicted in the HDD 2-2, that is, the HDD 2-2 is the disconnecting target that is to be disconnected from the magnetic disk apparatus 1. The failure generated or predicted in the HDD 2-2 is detectable by a known method such as detecting that a number of access retries with respect to the HDD 2-2 has exceeded a predetermined value or detecting that a number of access retries within a predetermined time has exceeded a prescribed value.

FIG. 1 is a diagram for explaining a state where an abnormality such as a failure is generated in the HDD 2-2 in a state where the HDD 2-2 is operating, that is, in use.

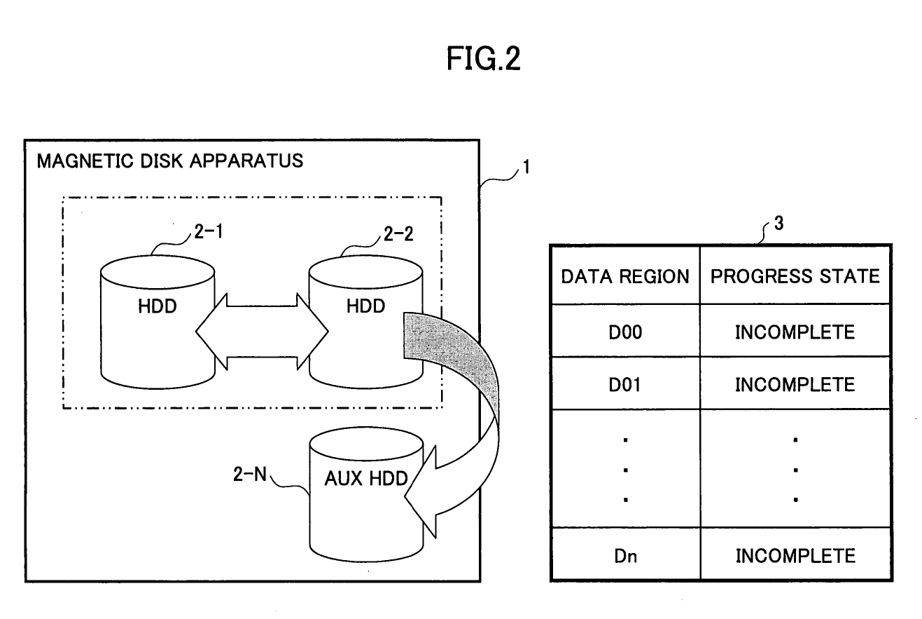

FIG. 2 is a diagram for explaining a data transfer that is carried out by reading the data stored in the HDD 2-2 in which the abnormality is detected, and transferring the read data to an auxiliary HDD 2-N. When starting the data transfer, a data transfer management table 3 which manages the progress state is prepared within the magnetic disk apparatus 1 or within a host apparatus (not shown). The data transfer management table 3 records the progress state of the data transfer, including whether the data transfer was incomplete (unsuccessful or failed) or completed (successful), with respect to each of data regions D00 through Dn within the HDD 2-2. In FIGS. 2 through 5, the data transfer management table 3 is shown on the right side of each figure. FIG. 2 shows the data transfer management table 3 at a point in time when the data transfer process is started.

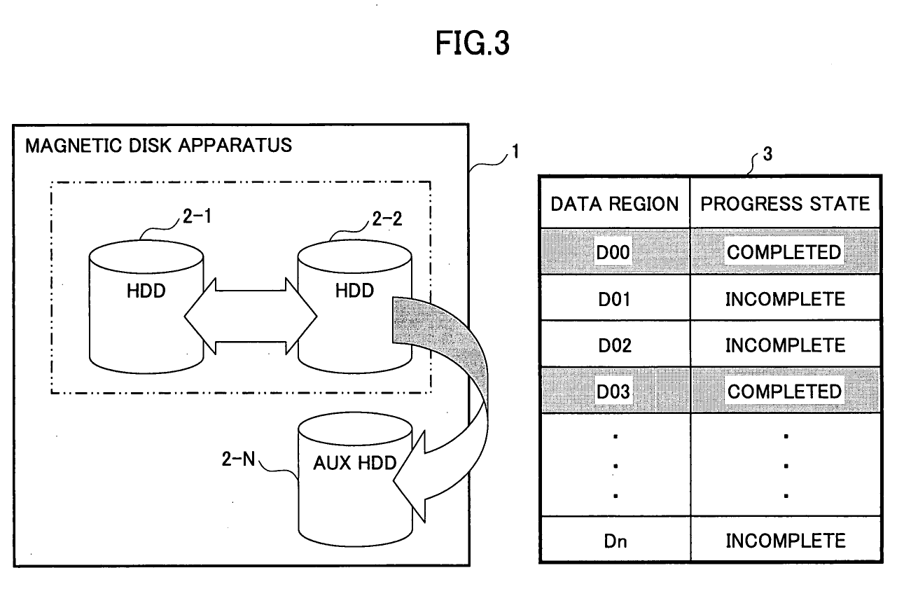

FIG. 3 is a diagram for explaining the management of the information indicating whether or not the data transfer was successful. In FIG. 3, it is assumed for the sake of convenience that the data transfer of the HDD 2-2 was successful for the data region D01, unsuccessful for the data region D02, successful for the data region D03, . . . , and unsuccessful for the data region Dn. Whether the data transfer was successful or unsuccessful is reflected to the data transfer management table 3 at all times. FIG. 3 shows the data transfer management table 3 at a point in time when the data transfer process for the data that can be transferred from the HDD 2-2 to the HDD 2-N is completed.

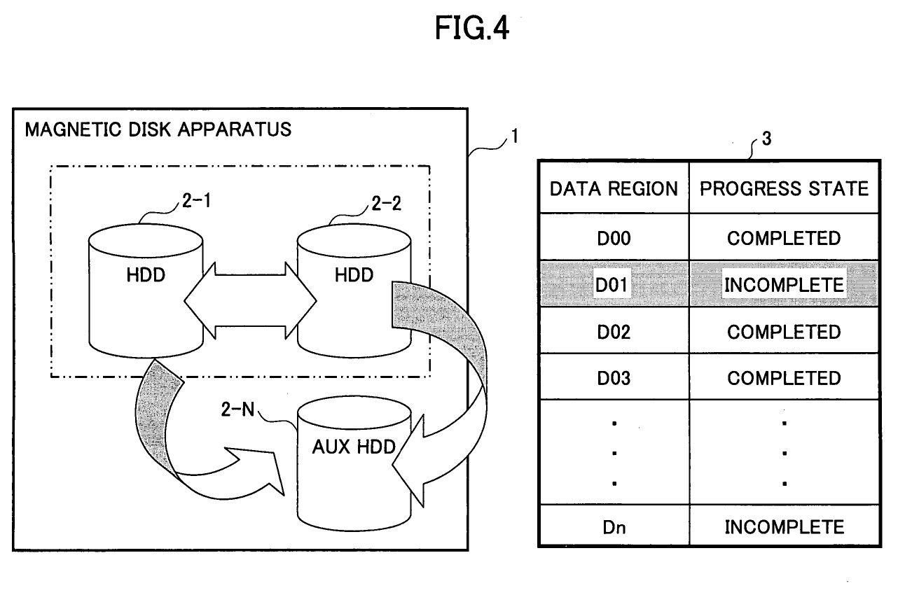

FIG. 4 is a diagram for explaining the remedying of a region for which the data transfer was unsuccessful. When the data transfer from the disconnecting target HDD 2-2 is completed, the data regions D01, . . . for which the data transfer was incomplete (unsuccessful) are detected based on the data transfer management table 3, and the redundant data are read from the HDD (redundant HDD) 2-1 which stores the same data as the HDD 2-2 so as to write the read redundant data to the auxiliary HDD 2-N. The data transfer from the HDD 2-2 is substantially completed by writing the redundant data from the HDD 2-1 to the auxiliary HDD 2-N, and the result of this data transfer is reflected to the data transfer management table 3 at all times. FIG. 4 shows the data transfer management table 3 at a point in time before the reading and transfer of the data from the HDD 2-1 is started.

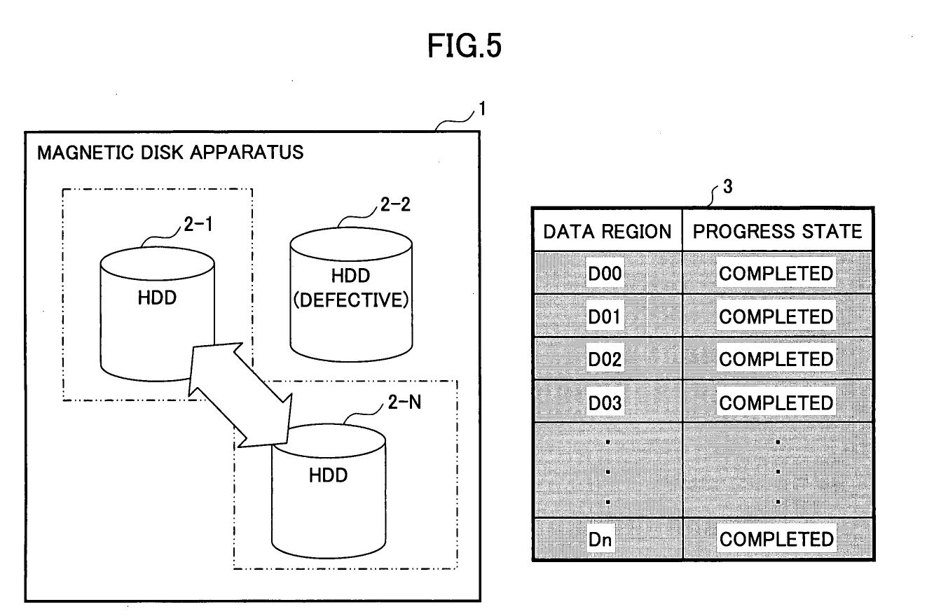

FIG. 5 is a diagram for explaining the disconnection of the disconnecting target HDD 2-2 from the magnetic disk apparatus 1. When a data region for which the data transfer was incomplete (unsuccessful) no longer exists in the data transfer management table 3, that is, when the data transfer of all of the data regions D01 through Dn is completed, the transfer of all of the data stored in the disconnecting target HDD 2-2 to the auxiliary HDD 2-N has been completed. Hence, the disconnecting target HDD 2-2 is disconnected from the magnetic disk apparatus 1. Thereafter, a new HDD is connected to the magnetic disk apparatus 1 if necessary.

Therefore, according to this embodiment, the data to be transferred are basically read from the disconnecting target HDD 2-2 and written to the auxiliary (that is, another) HDD 2-N. When transferring the data, the information related to the data transfer is managed by the data transfer management table 3. With respect to the data region for which the writing of data (data transfer) was successful, information indicating the successful writing (data transfer) is recorded in the data transfer management table 3. On the other hand, with respect to the data region for which the writing of data (data transfer) was unsuccessful due to a read error or unsuccessful reading from the disconnecting target HDD 2-2, for example, information indicating the unsuccessful writing (data transfer) is recorded in the data transfer management table 3. By carrying out such a procedure, all data that are readable from the disconnecting target HDD 2-2 are transferred from the HDD 2-2 to the auxiliary (that is, another) HDD 2-N. When carrying out the data transfer, a disconnecting process to disconnect the HDD 2-2 from the magnetic disk apparatus 1 is not carried out even if an abnormality is detected in the disconnecting target HDD 2-2. With respect to the data region for which the writing of data (data transfer) was unsuccessful, the redundant data stored in the HDD (redundant HDD) 2-1 are used to form the data that are to be transferred to the HDD 2-N at the transfer destination, based on the information managed by the data transfer management table 3, and the formed data are written to the transfer destination HDD 2-N. The process of forming the data to be transferred to the transfer destination HDD 2-N by utilizing the redundant data and the process of transferring the formed data to the transfer destination HDD 2-N, that are carried out with respect to the region for which the data transfer was unsuccessful, may be carried out at a timing corresponding to a point in time when the reading of the data from the disconnecting target HDD 2-2 fails or corresponding to a point in time when the reading of all data readable from the disconnecting target HDD 2-2 is completed.

Hence, according to this embodiment, it is possible to carry out the data transfer between the HDDs 2-2 and 2-N while maintaining as much as possible the redundancy of the data to be stored within the magnetic disk apparatus 1 between the HDDs 2-1 and 2-N.

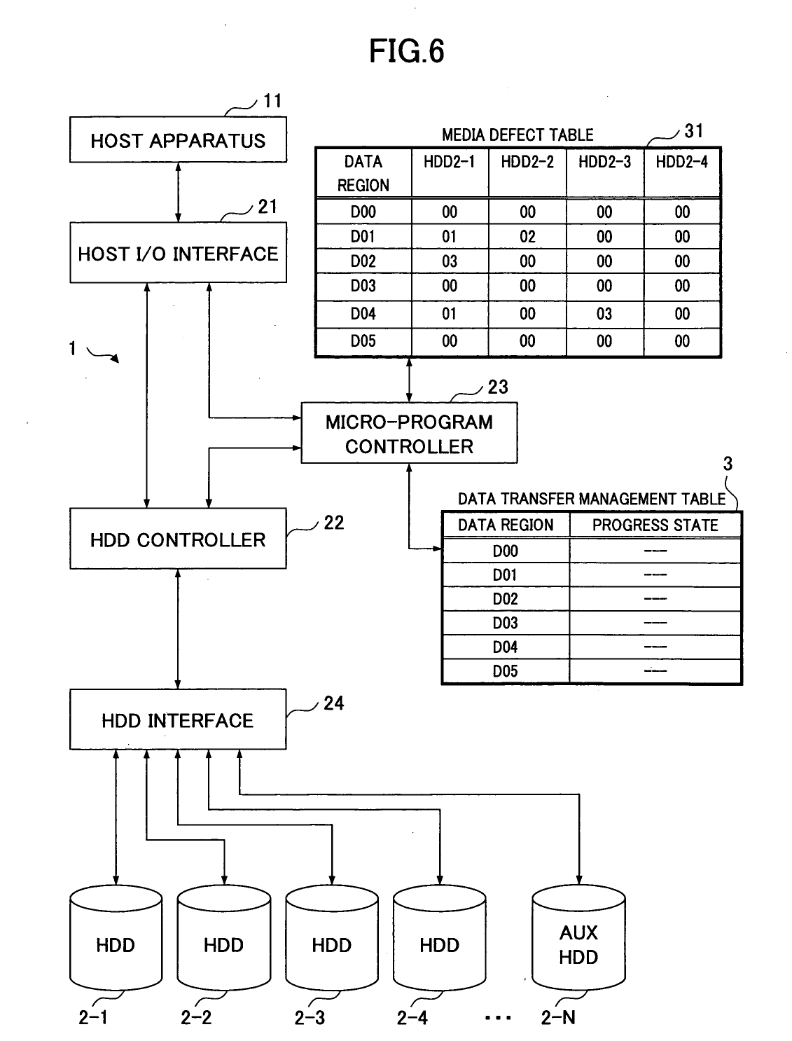

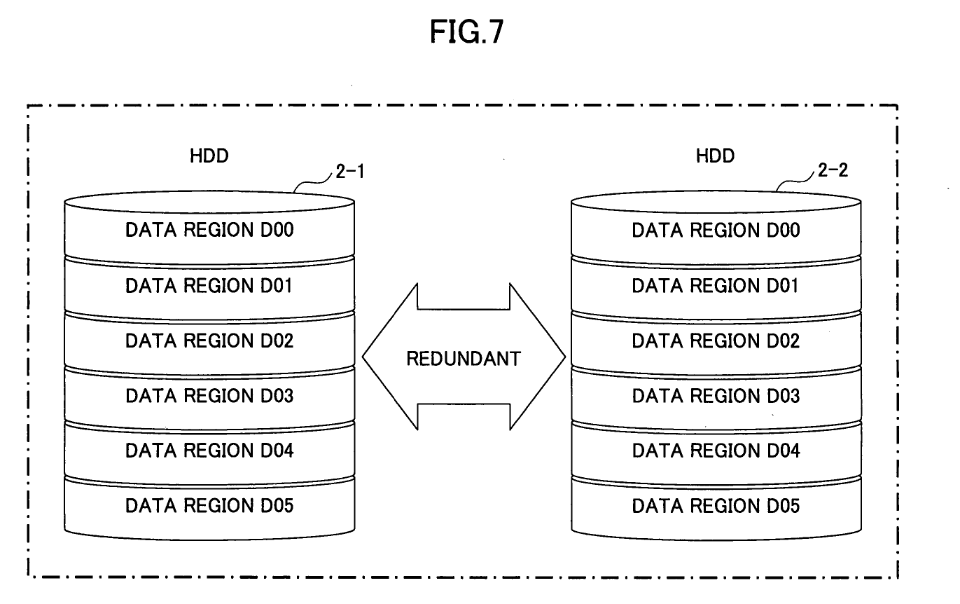

FIG. 6 is a system block diagram showing an important part of an embodiment of a storage apparatus according to the present invention, and FIG. 7 is a diagram showing the data regions of the HDDs. In this embodiment of the storage apparatus, the present invention is applied to a magnetic disk apparatus, and it is assumed for the sake of convenience that the above described embodiment of the data transfer method is employed.

The magnetic disk apparatus 1 shown in FIG. 6 is connected to a host apparatus (or server) 11. The host apparatus 11 is formed by a general-purpose computer, for example. The magnetic disk apparatus 1 includes a host input and output (I/O) interface 21, an HDD controller 22, a micro-program controller 23, an HDD interface 24, HDDs 2-1 through 2-N, a data transfer management table 3, and a media deflect table 31. The host I/O interface 21 provides an interface between the magnetic disk apparatus 1 and the host apparatus 11. The HDD interface 24 provides an interface between the main body of the magnetic disk apparatus 1 and the HDDs 2-1 through 2-N. The HDD controller 22 controls access requests with respect to the HDDs 2-1 through 2-N, based on access instructions from the host apparatus 11. The micro-program controller 23 manages the data transfer management table 3 and the media defect table 31.

The data transfer management table 3 manages the progress of the data transfer when disconnecting the HDD from the magnetic disk apparatus 1. The data transfer management table 3 is stored in at least one of the HDDs 2-1 through 2-N or, in another storage part. In this embodiment, the data transfer management table 3 indicates the progress state of the data transfer for each of the data regions D00 through D05 of the disconnecting target HDD 2-2. The media defect table 31 manages locations of the media defects in the HDDs 2-1 through 2-N that are connected to the magnetic disk apparatus 1. The media defect table 31 is stored in at least one of the HDDs 2-1 through 2-N or, in another storage part. In this embodiment, the media defect table 31 indicates the number of media errors detected in each of the data regions D00 through D05 of each of the HDDs 2-1, 2-2, 2-3, 2-4, . . . . The storage parts which store the data transfer management table 3 and the media defect table 31 may be the same or, may be different.

In a case where the media error is detected in the HDD that is accessed in response to an HDD access request from the HDD controller 22, the micro-program controller 23 registers the location of the detected media error as a media defect location in the media defect table 31. The media defect table 31 is updated at all times depending on the location, that is, the data region where the media error is generated, and the number of times the media error is generated. The media defect table 31 may employ a management system that manages a logical block address as one unit or, a data region formed by a collection of a plurality of blocks as one unit.

The data transfer management table 3 segments (or divides) transferring data into a segment for every logical block address or specific data region, under the management of the micro-program controller 23, and manages the progress state of the data transfer including whether the data transfer for the segment was successful or unsuccessful.

The data stored in the HDDs 2-1 through 2-N are stored in storage regions that are formed by a plurality of HDDs called a Redundant Arrays of Independent (or Inexpensive) Disks group (RAID group) in order to maintain data redundancy. For example, in a case where the RAID group is formed by 2 HDDs 2-1 and 2-2, the 2 HDDs 2-1 and 2-2 store identical data. In other words, the data stored in the HDD 2-1 are the same as the data stored in the HDD 2-2. In addition, when the data stored in the HDD 2-1 are updated, the data stored in the HDD 2-2 are similarly updated.

In FIG. 7, the HDDs 2-1 and 2-2 form a single RAID group, and the RAID1 system is presumed. The RAID1 system carries out the so-called mirroring, so that the same data are simultaneously written into 2 HDDs. When an access request (read process) is generated from the host apparatus 11, the access is only made to one of the redundantly written data. For this reason, in the case where the RAID group is formed by the 2 HDDs 2-1 and 2-2, the access request is generated with respect to only one of the 2 HDDs 2-1 and 2-2. In the case shown in FIG. 7, the HDDs 2-1 and 2-2 belong to the same RAID group and store the same data. Hence, the HDD 2-1 or the HDD 2-2 is accessed by the read process. If the access to the HDD 2-2 is unsuccessful due to a media error or the like when the read process is carried out with respect to the HDD 2-2, a read process is carried out with respect to the other HDD 2-1, of the same RAID group, storing the same data as the HDD 2-2.

In FIGS. 6 and 7, 6 data regions D00 through D05 as shown. However, the number of data regions may of course be set to an arbitrary number.

When a read access request with respect to the data stored in the HDD 2-2, for example, is generated from the HDD controller 22 based on an instruction from the host apparatus 11, the micro-program controller 23 makes a reference in advance to the contents of the media defect table 31 with respect to the related HDD 2-1 including the data redundantly written by the magnetic disk apparatus 1. In addition, the micro-program controller 23 acquires, from the contents (error log) of the referred media defect table 31, the error log and number of generated errors of each required data region, and compares the error log and number of generated errors for every redundantly written data or, for every HDD written with the redundantly written data. Based on the result of the comparisons made, the micro-program controller 23 utilizes the data or HDD having no error log or having a small number of generated errors, to build a schedule for reading the required data. The HDD controller 22 reads the required data stored in the HDD according to the schedule built by the micro-program controller 23.

For example, when replacing the HDD 2-2 that stores data due to failure or the like of the HDD 2-2, the data transfer process is carried out to transfer the stored data from the disconnecting target (or replacing target) HDD 2-2 to the auxiliary HDD 2-N. The micro-program controller 23 updates and manages at all times the progress state including the data transfer result (successful or unsuccessful data transfer) with respect to the data transfer management table 3. If the micro-program controller 23 detects an error event in which the data read process from a target region (segment) of the disconnecting target HDD 2-2 fails during the data transfer process, the micro-program controller 23 registers in the data transfer management table 3 information indicating that the data transfer process was unsuccessful with respect to the target data region (segment). If the data transfer process was successful with respect to the target data region (segment), the micro-program controller 23 registers in the data transfer management table 3 information indicating that the data transfer process was successful with respect to the target data region (segment).

In a case where an error event is frequently generated in the disconnecting target HDD 2-2 when carrying out the data transfer process, the data read process is continued as much as possible to read as much of the stored data from the disconnecting target HDD 2-2 as possible, and the disconnecting target HDD 2-2 is not disconnected from the magnetic disk apparatus 1 at this stage.

When the data read process from the disconnecting target HDD 2-2 is completed, the micro-program controller 23 refers to the data transfer management table 3 and searches the region for which the data transfer process is incomplete. If the region for which the data transfer process is incomplete is detected, the data transfer process for this region is carried out by reading the necessary data from the redundant HDD 2-1 which stores the same data as the disconnecting target HDD 2-2 under the control of the HDD controller 22. The disconnecting target HDD 2-2 is disconnected from the magnetic disk apparatus 1 and replaced by a new HDD at the point in time when or, after the data transfer process to the auxiliary HDD 2-N is completed. By using the disconnecting target HDD 2-2 at the data transfer source as much as possible by utilizing the data transfer management table 3, it is possible to carry out the data transfer between the HDDs 2-2 and 2-N while maintaining the redundancy of the data stored within the magnetic disk apparatus 1 as much as possible between the HDDs 2-1 and 2-N.

Accordingly, by utilizing the media defect table 31 and the data transfer management table 3, it is possible to suppress the generation of the retry process and to efficiently replace the HDD in a state where the data redundancy is maintained to a maximum.

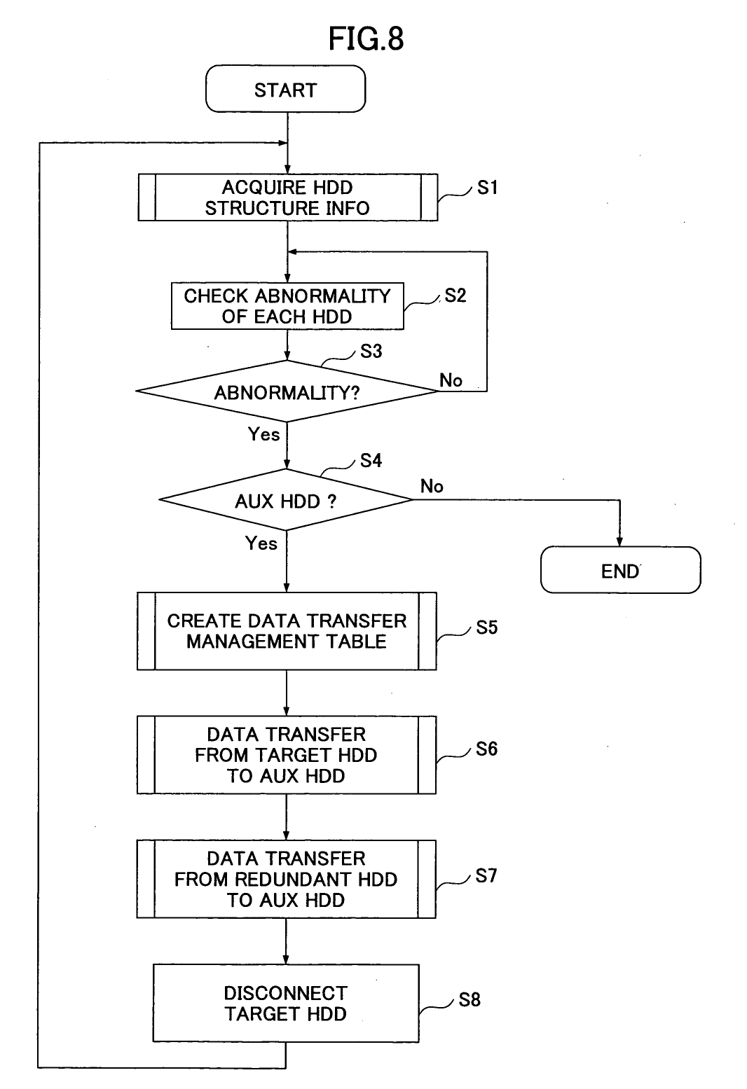

Next, a description will be given of a program stored in an embodiment of a computer-readable storage medium according to the present invention, by referring to FIGS. 8 through 15. The program stored in this embodiment of the computer-readable storage medium causes a computer system that includes a processor such as a CPU and a memory to carry out the data transfer process described above. In this embodiment, the program causes the computer system to realize the functions of the micro-program controller 23, but the program may also cause the computer system to realize at least a part of the functions of the HDD controller 22.

FIG. 8 is a flow chart for explaining the data transfer process that is carried out based on the program stored in this embodiment of a computer-readable storage medium according to the present invention. In FIG. 8, a step S1 carries out a process of acquiring information (HDD structure information) related to the HDDs 2-1 through 2-N that are connected to the magnetic disk apparatus 1. The HDD structure information indicates the HDDs that are connected to the magnetic disk apparatus 1.

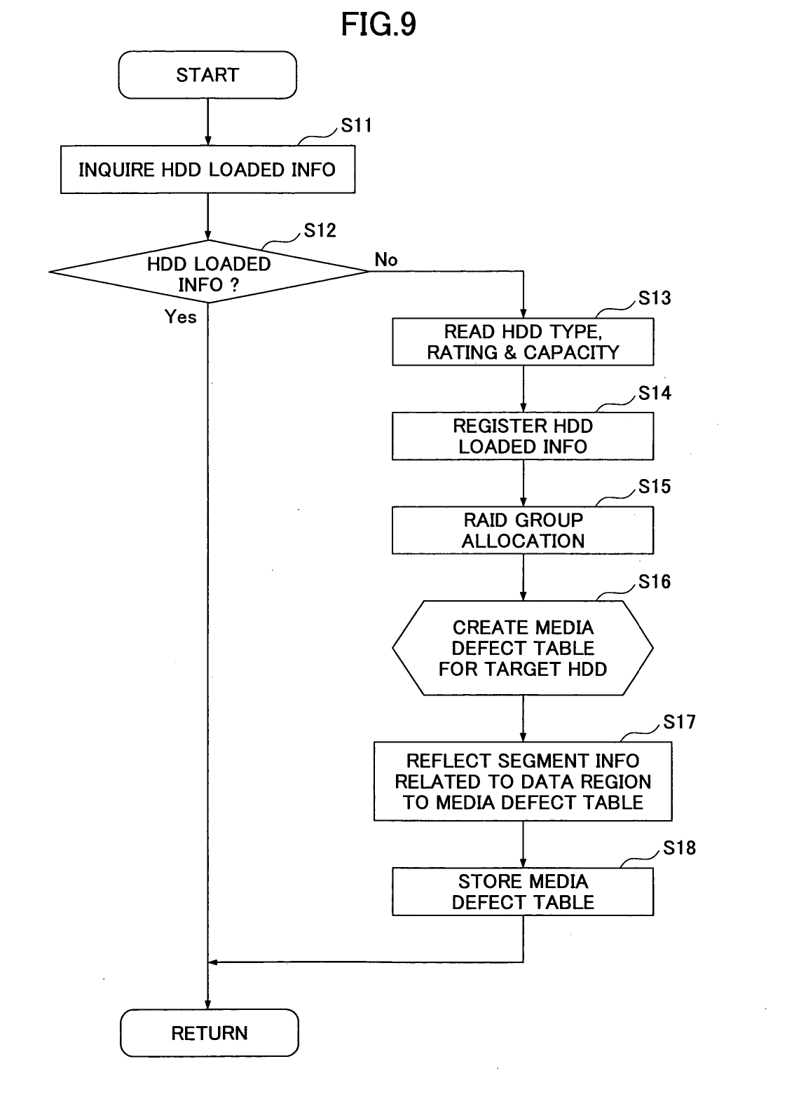

FIG. 9 is a flow chart for explaining the process of acquiring HDD structure information. In FIG. 9, a step S11 inquires HDD loaded information, and a step S12 decides whether or not the HDD loaded information related to the HDDs 2-1 through 2-N that are connected to the magnetic disk apparatus 1 is registered within the magnetic disk apparatus 1. The HDD loaded information indicates the HDD type, the rating, the capacity and the like of each of the HDDs connected to the magnetic disk apparatus 1. If the HDD loaded information is stored in a storage part (not shown) within the magnetic disk apparatus 1, for example, and the decision resulting the step S12 is YES, the process advances to a step S2 shown in FIG. 8.

On the other hand, if the decision result in the step S12 is NO, a step S13 reads the HDD type, the rating and the capacitance of the HDDs 2-1 through 2-N that are connected to the magnetic disk apparatus 1, from each of the HDDs 2-1 through 2-N, and a step S14 registers the HDD loaded information in the storage part within the magnetic disk apparatus 1 based on the read information. The storage part into which the HDD loaded information is registered may be one of the HDDs 2-1 through 2-N. A step S15 makes a RAID group allocation and groups the HDDs 2-1 through 2-N into respective RAID groups. A step S16 creates the media defect table 31 which indicates the number of media errors detected in each of the data regions D00 through D05 of each of the HDDs 2-1 through 2-N. A step S17 reflects segment information (for example, the size of the data region) related to the data region to the media defect table 31. A step S18 registered the created media defect table 31 in the storage part within the magnetic disk apparatus 1, and the process advances to the step S2 shown in FIG. 8.

Returning now to the description of FIG. 8, the step S2 checks each of the HDDs 2-1 through 2-N, and a step S3 decides whether or not an abnormality is detected in any of the HDDs 2-1 through 2-N. The process returns to the step S2 if the decision result in the step S3 is NO. On the other hand, if the decision result in the step S3 is YES, a step S4 decides whether or not the auxiliary HDD 2-N is connected to the magnetic disk apparatus 1. The auxiliary HDD 2-N does not need to be formed a specific HDD, and may be formed by any arbitrary HDD that may be utilized as the auxiliary HDD. The process ends if the decision result in the step S4 is NO. If the decision result in the step S4 is YES, a step S5 carries out a process to create the data transfer management table 3.

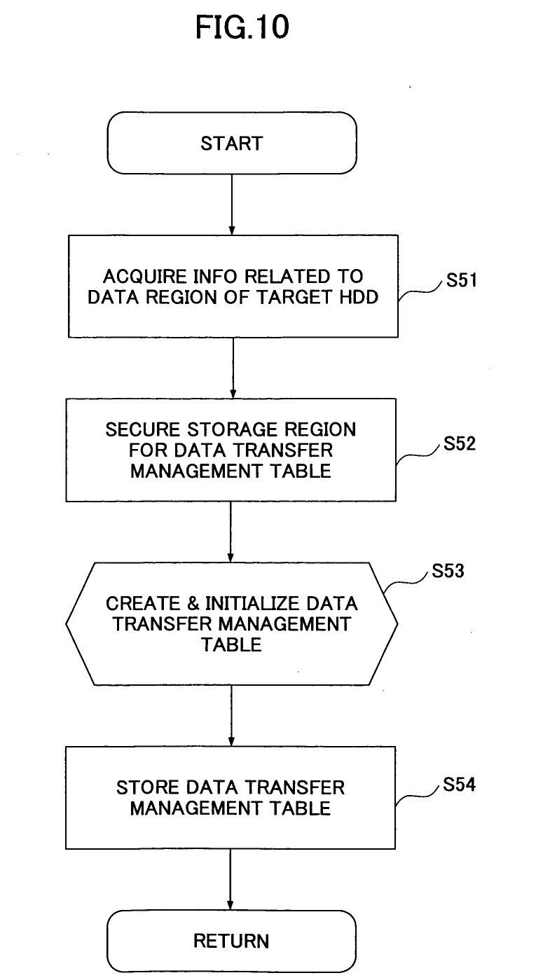

FIG. 10 is a flow chart for explaining the process of creating the data transfer management table 3. In FIG. 10, a step S51 acquires information related to the data regions of the disconnecting target (or replacing target) HDD 2-2, and a step S52 secures a storage region for the data transfer management table 3 in the storage part. A step S53 creates and initializes the data transfer management table 3 for recording the progress state of the data transfer with respect to each data region of the disconnecting target HDD 2-2. A step S54 registers the created data transfer management table 3 in the storage part, and the process advances to a step S6 shown in FIG. 8.

Returning now to the description of FIG. 8, the step S6 carries out a data transfer process from the disconnecting target (replacing target) HDD 2-2 to the auxiliary HDD 2-N.

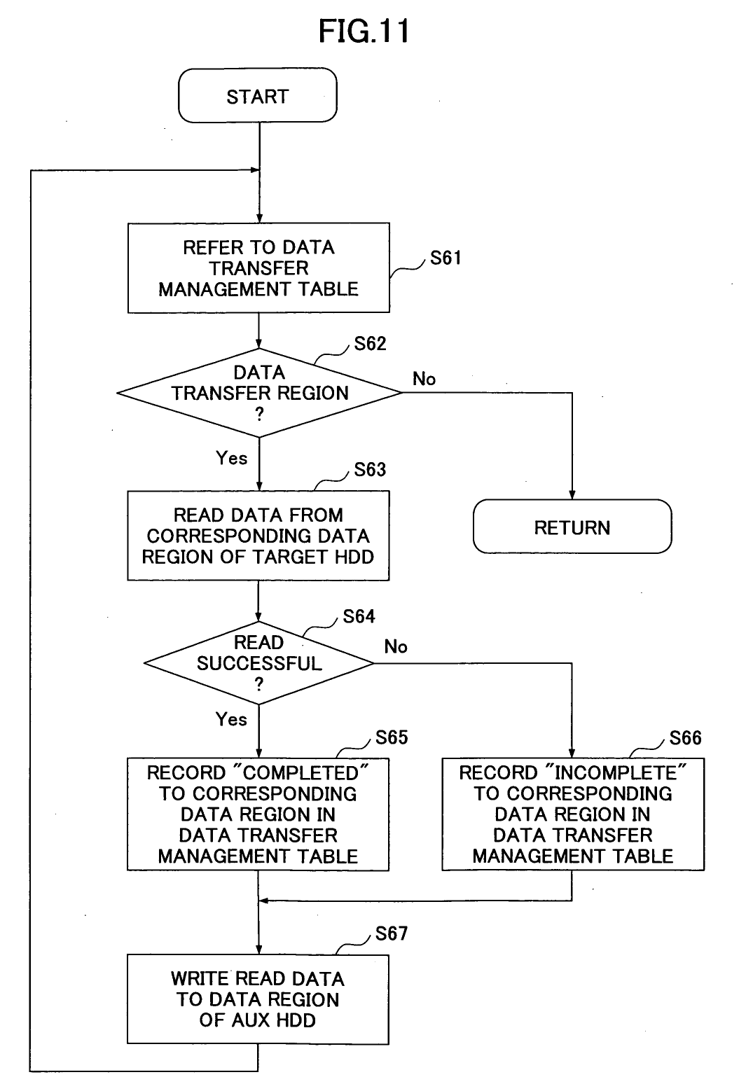

FIG. 11 is a flow chart for explaining the data transfer process from the disconnecting target (replacing target) HDD 2-2 to the auxiliary HDD 2-N. In FIG. 11, a step S61 refers to the data transfer management table 3, and a step S62 decides whether or not there exists a data region for which the data transfer process is to be carried out. The process advances to a step S7 shown in FIG. 8 if the decision result in the step S62 is NO. On the other hand, if the decision result in the step S62 is YES, a step S63 reads the data from one data region, of the disconnecting target HDD 2-2, for which the data transfer process is to be carried out. A step S64 decides whether or not the data read process from the one data region was successful. If the decision result in the step S64 is YES, a step S65 records “completed (or successful)” with respect to the corresponding data region in the data transfer management table 3, and the process advances to a step S67. On the other hand, if the decision result in the step S64 is NO, a step S66 records “incomplete (or unsuccessful)” with respect to the corresponding data region in the data transfer management table 3, and the process advances to the step S67. The step S78 writes the read data to the corresponding data region of the auxiliary HDD 2-N, and the process returns to the step S61.

Returning now to the description of FIG. 8, the step S7 carries out a data transfer process from the redundant HDD 2-1 to the auxiliary HDD 2-N.

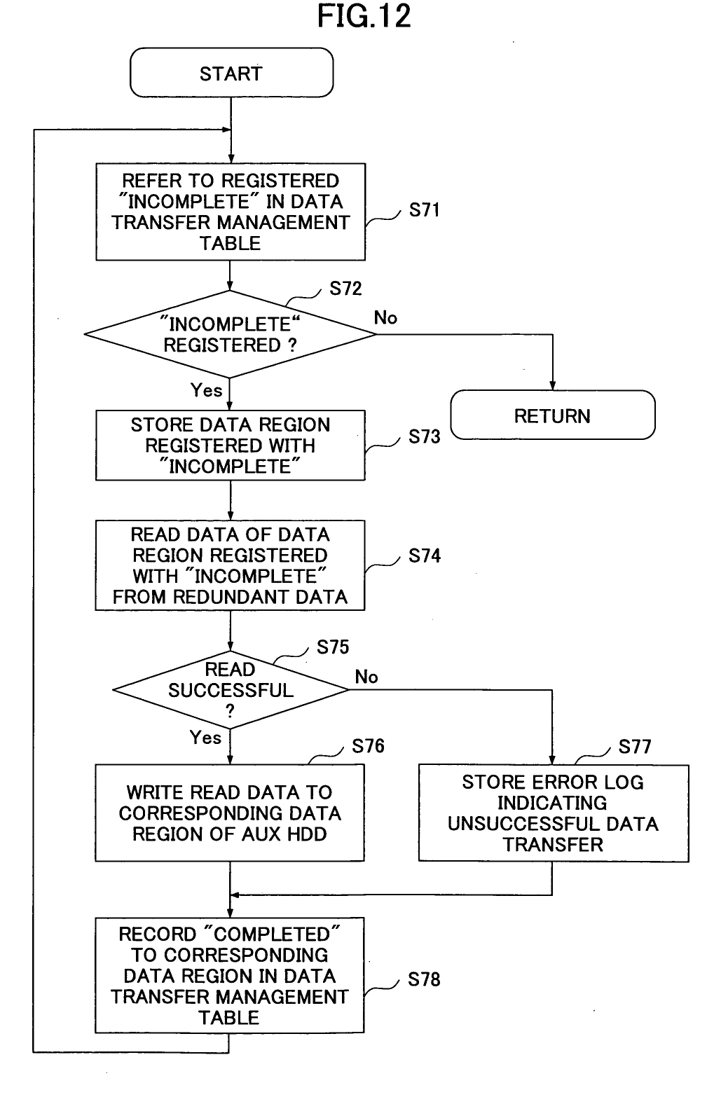

FIG. 12 is a flow chart for explaining the data transfer process from the redundant HDD 2-1 to the auxiliary HDD 2-N. In FIG. 12, a step S71 refers to the data transfer management table 3, and a step S72 decides whether or not there exists a data region having “incomplete (or unsuccessful)” recorded in the data transfer management table 3. The process advances to a step S8 shown in FIG. 8 if the decision result in the step S72 is NO. On the other hand, if the decision result in the step S72 is YES, a step S73 stores the data region recorded with “incomplete (or unsuccessful)”. A step S74 reads from the redundant HDD 2-1 the data of the data region corresponding to the stored data region (of the HDD 2-2) recorded with “incomplete (or unsuccessful)”. A step S75 decides whether or not the data read process from the redundant HDD 2-1 was successful. If the decision result in the step S75 is YES, a step S76 carries out a data transfer process to write the data read from the redundant HDD 2-1 to the auxiliary HDD 2-N, and the process advances to a step S78. In addition, if the decision result in the step S75 is NO, a step S77 stores log information indicating that the data transfer process from the redundant HDD 2-1 was unsuccessful (failed), and the process advances to the step S78. The step S78 records “completed (or successful)” in the data transfer management table 3 with respect to the data region for which the data transfer process was made, and the process returns to the step S71.

Returning now to the description of FIG. 8, the step S8 sends to the host apparatus 11 a message or the like indicating that the disconnecting target (replacing target) HDD 2-2 may be disconnected from the magnetic disk apparatus 1, and the process returns to the step S1. In other words, after the step S8 judges that the disconnecting target HDD 2-2 may be disconnected from the magnetic disk apparatus 1, the disconnection of the disconnecting target HDD 20. 2-2 from the magnetic disk apparatus 1 is permitted, and the connection of the new HDD if necessary is also permitted.

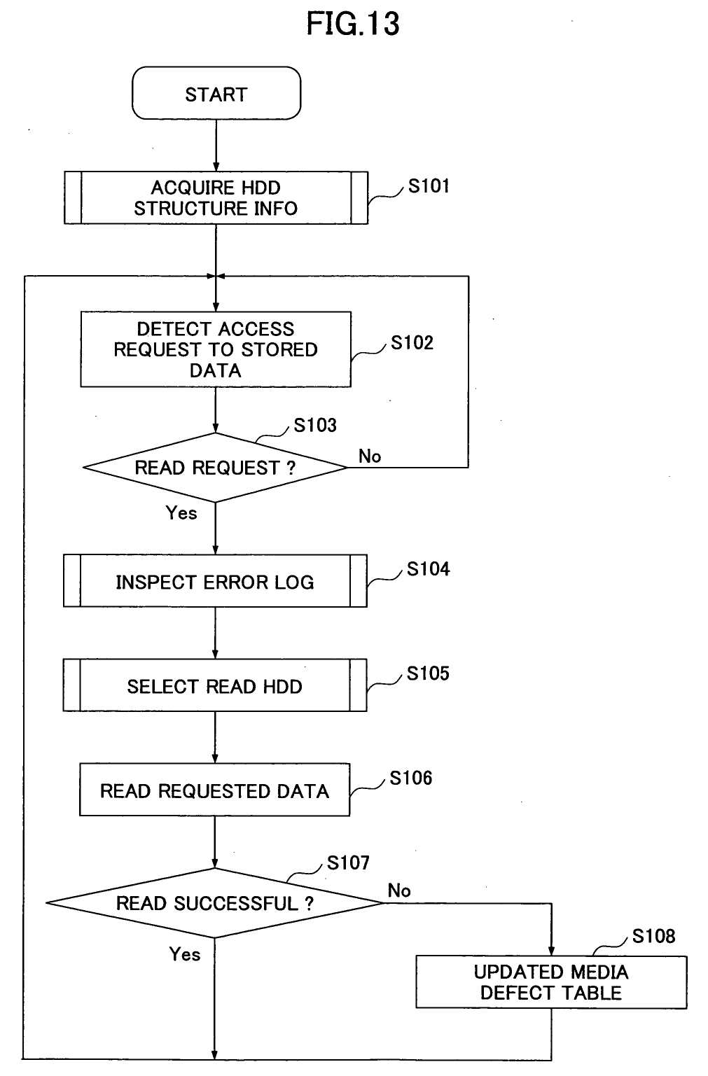

FIG. 13 is a flow chart for explaining the data read process utilizing the media defect table 31. In FIG. 13, a step S101 carries out a process of acquiring the information (HDD structure information) related to the HDDs 2-1 through 2-N that are connected to the magnetic disk apparatus 1, in order to acquire the HDD structure information. The process of acquiring the HDD structure information carried out by the step S101 may be the same as that shown in FIG. 9 described above. A step S102 detects an access request to stored data, and a step S103 decides whether or not the access request is a read request (read process). The process returns to the step S102 if the decision result in the step S103 is NO. On the other hand, if the decision result in the step S103 is YES, the process advances to a step S104.

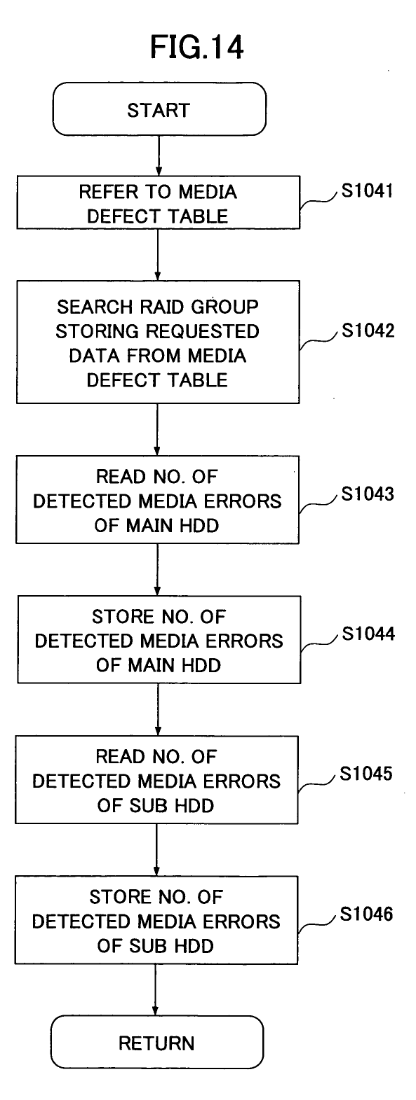

FIG. 14 is a flow chart for explaining a process of inspecting the error log (or error generation log) that is carried out by the step S104. In FIG. 14, a step S1041 refers to the media defect table 31, and a step S1042 searches for the RAID group that stores the data requested by the access request, from the media defect table 31. A step S1043 reads from the media defect table 31 the number of detected media errors with respect to a main HDD (for example, the HDD 2-2) of the searched RAID group. A step S1044 stores in the storage part the number of detected media errors with respect to the main HDD (for example, HDD 2-2) read from the media defect table 31. In this embodiment, it is assumed that, of the two HDDs forming the RAID group, one HDD is utilized as the main HDD and the other HDD is utilized as a sub HDD for use when an overload or abnormality is generated. A step S1045 reads from the media defect table 31 the number of detected media errors with respect to the sub HDD (for example, the HDD 2-1) of the searched RAID group. A step S1046 stores in the storage part the number of detected media errors with respect to the sub HDD (for example, HDD 2-1) read from the media defect table 31, and the process advances to a step S105 shown in FIG. 13.

Returning now to the description of FIG. 13, the step S105 carries out a process of selecting a read HDD.

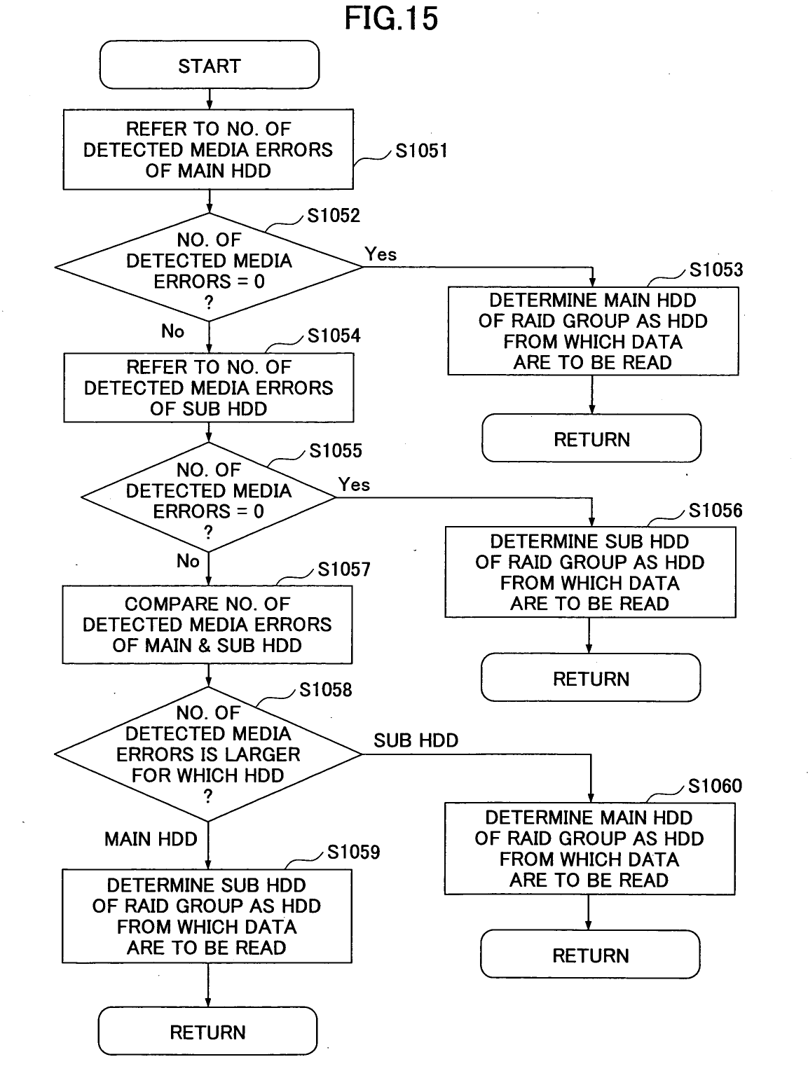

FIG. 15 is a flow chart for explaining the process of selecting the read HDD. In FIG. 15, a step S1051 refers to the number of detected media errors of the main HDD stored in the storage part, and a step S1052 decides whether or not the number of detected media errors for the main HDD is 0. If the decision result in the step S1052 is YES, a step S1053 determines the HDD of the RAID group from which the requested data is to be read to the main HDD, and the process advances to a step S106 shown in FIG. 13. On the other hand, if the decision result in the step S1052 is NO, a step S1054 refers to the number of detected media errors of the sub HDD stored in the storage part, and a step S1055 decides whether or not the number of detected media errors for the sub HDD is 0. If the decision result in the step S1055 is YES, a step S1056 determines the HDD of the RAID group from which the requested data is to be read to the sub HDD, and the process advances to the step S106 shown in FIG. 13.

If the decision result in the step S1055 is NO, a step S1057 compares the number of detected media errors for the main HDD and the number of detected media errors for the sub HDD. A step S1058 decides whether the number of detected media errors for the main HDD is larger or, the number of detected media errors for the sub HDD is larger. If the number of detected media errors for the main HDD is larger, a step S1059 determines the HDD of the RAID group from which the requested data is to be read to the sub HDD, and the process advances to the step S106 shown in FIG. 13. On the other hand, if the number of detected media errors for the sub HDD is larger, a step S1060 determines the HDD of the RAID group from which the requested data is to be read to the main HDD, and the process advances to the step S106 shown in FIG. 13.

Returning now to the description of FIG. 13, the step S106 reads the requested data from the determined one of the HDDs forming the RAID group, and a step S107 decides whether or not the read process was successful. The process returns to the step S102 if the decision result in the step S107 is YES. If the decision result in the step S107 is NO, a step S108 counts up the number of detected media errors with respect to the HDD from which the data was read by the read process so as to update the media defect table 31, and the process returns to the step S102.

In the embodiments described above, the present invention is applied to the magnetic disk apparatus. However, the present invention is of course similarly applicable to other storage apparatuses such as optical disk apparatuses and magneto-optic disk apparatuses. In addition, the recording medium used by the storage apparatus is not limited to disks, and the storage apparatus may use other kinds of recording media including card-shaped recording media, tape-shaped recording media and storage devices such as semiconductor memory devices.

Further, the present invention is not limited to these embodiments, but various variations and modifications may be made without departing from the scope of the present invention.

What is claimed is

1. A data transfer method for transferring data stored in a first storage part to a second storage part within a storage apparatus, comprising:
a first step transferring all data stored in units of data regions within the first storage part to the second storage part; and
a second step transferring, with respect to each data region for which a data transfer by the first step is unsuccessful, redundant data to the second storage part from a third storage part which stores the redundant data identical to the data stored in the first storage part.

2. The data transfer method as claimed in claim 1, further comprising:
a step permitting disconnection of the first storage part from the storage apparatus after the first and second steps end.

3. The data transfer method as claimed in claim 1, further comprising:
a step updating at all times a data transfer management table which indicates a progress state of the data transfer, including whether the data transfer with respect to each data region within the first storage part is successful or unsuccessful,
wherein the first step carries out the data transfer based on the data transfer management table.

4. The data transfer method as claimed in claim 3, further comprising:
a step updating at all times a media defect table that manages locations of media defects in each storage part within the storage apparatus,
wherein the second step carries out the data transfer based on the data transfer management table and the media defect table.

5. The data transfer method as claimed in claim 4, wherein the media defect table indicates a number of media errors detected in each data region of each storage part within the storage apparatus.

6. The data transfer method as claimed in claim 1, further comprising:
a step updating at all times a media defect table that manages locations of media defects in each storage part within the storage apparatus,
wherein the first step reads the redundant data from one of the first and third storage parts having a smaller number of media defects based on the media defect table, and transfers the read data to the second storage part.

7. A storage apparatus comprising:
a first storage part;
a second storage part;
a third storage part; and
a control part configured to control data transfers among the first, second and third storage parts,
wherein the control part transfers all data stored in units of data regions within the first storage part to the second storage part, and transfers, with respect to each data region for which a data transfer is unsuccessful, redundant data to the second storage part from the third storage part which stores the redundant data identical to the data stored in the first storage part.

8. The storage apparatus as claimed in claim 7, wherein the control part permits disconnection of the first storage part from the storage apparatus after the data transfer to the second storage part ends.

9. The storage apparatus as claimed in claim 7, wherein the control part updates at all times a data transfer management table which indicates a progress state of the data transfer, including whether the data transfer with respect to each data region within the first storage part is successful or unsuccessful, and carries out the data transfer based on the data transfer management table.

10. The storage apparatus as claimed in claim 9, wherein the control part updates at all times a media defect table that manages locations of media defects in each storage part within the storage apparatus, and carries out the data transfer based on the data transfer management table and the media defect table.

11. The storage apparatus as claimed in claim 10, wherein the media defect table indicates a number of media errors detected in each data region of each storage part within the storage apparatus.

12. The storage apparatus as claimed in claim 7, wherein the control part updates at all times a media defect table that manages locations of media defects in each storage part within the storage apparatus, and reads the redundant data from one of the first and third storage parts having a smaller number of media defects based on the media defect table and transfers the read data to the second storage part.

13. The storage apparatus as claimed in claim 7, wherein the first, second and third storage parts are disk drives.

14. A computer-readable storage medium which stores a program for causing a computer to transfer data stored in a first storage part to a second storage part within a storage apparatus, said program comprising:
a first procedure causing the computer to transfer all data stored in units of data regions within the first storage part to the second storage part; and
a second procedure causing the computer to transfer, with respect to each data region for which a data transfer by the first step is unsuccessful, redundant data to the second storage part from a third storage part which stores the redundant data identical to the data stored in the first storage part.

15. The computer-readable storage medium as claimed in claim 14, wherein said program further comprises:
a procedure causing the computer to permit disconnection of the first storage part from the storage apparatus after the first and second procedures end.

16. The data transfer method as claimed in claim 14, wherein said program further comprises:
a procedure causing the computer to update at all times a data transfer management table which indicates a progress state of the data transfer, including whether the data transfer with respect to each data region within the first storage part is successful or unsuccessful,
wherein the first procedure causes the computer to carry out the data transfer based on the data transfer management table.

17. The computer-readable storage medium as claimed in claim 16, wherein said program further comprises:
a procedure causing the computer to update at all times a media defect table that manages locations of media defects in each storage part within the storage apparatus,
wherein the second procedure causes the computer to carry out the data transfer based on the data transfer management table and the media defect table.

18. The computer-readable storage medium as claimed in claim 17, wherein the media defect table indicates a number of media errors detected in each data region of each storage part within the storage apparatus.

19. The computer-readable storage medium as claimed in claim 14, wherein said program further comprises:
a procedure causing the computer to update at all times a media defect table that manages locations of media defects in each storage part within the storage apparatus,
wherein the first procedure causes the computer to read the redundant data from one of the first and third storage parts having a smaller number of media defects based on the media defect table, and to transfer the read data to the second storage part.

20. A storage apparatus comprising:
a first storage part;
a second storage part; and
a control part configured to control transfer of data stored in the first storage part to the second storage part when an abnormality is generated in the first storage part,
wherein the first storage part is disconnected from the storage apparatus after the transfer of data from the first storage part to the second storage part is completed.

21. The storage apparatus as claimed in claim 20, wherein the abnormality is a failure that is generated or predicted in the first storage part.

22. The storage apparatus as claimed in claim 20, wherein the transfer of data from the first storage part to the second storage part is carried out in units of data regions, and the first storage part is disconnected from the storage apparatus after the transfer of data from the first storage part to the second storage part is completed for all data regions from which the transfer of data is possible.
